(19) United States
(12) Patent Application Publication
(10) Pub. No.: US 2020/0083332 A1
(43) Pub. Date: Mar. 12, 2020

(54) SEMICONDUCTOR DEVICE AND METHOD FOR FABRICATING THE SAME

(71) Applicant: Industrial Technology Research Institute, Hsinchu (TW)

(72) Inventors: Heng Lee, Taoyuan City (TW); Shin-Yi Huang, Hsinchu County (TW); Tao-Chih Chang, Taoyuan City (TW)

(73) Assignee: Industrial Technology Research Institute, Hsinchu (TW)

(21) Appl. No.: 16/561,023

(22) Filed: Sep. 5, 2019

Related U.S. Application Data
(60) Provisional application No. 62/726,990, filed on Sep. 5, 2018.

(30) Foreign Application Priority Data
Apr. 17, 2019 (TW) 108113351

(51) Int. Cl. H01L 29/24; H01L 29/66; H01L 29/78; H01L 21/02; H01L 29/51

(52) U.S. Cl. CPC H01L 29/24; H01L 29/66477; H01L 29/516; H01L 21/02565; H01L 29/78

(57) ABSTRACT

A semiconductor device includes a substrate, a channel layer, a first electrode layer, a second electrode layer, and a gate structure. The substrate includes a first gallium oxide layer. The channel layer is disposed on the substrate, where the channel layer is a second gallium oxide layer. The first electrode layer and the second electrode layer are disposed on the channel layer. The gate structure is disposed on the channel layer between the first electrode layer and the second electrode layer. The gate structure is on the channel layer or the gate structure has a bottom portion extending into the channel layer.

### CROSS-REFERENCE TO RELATED APPLICATION

This application claims the priority benefits of U.S. provisional application Ser. No. 62/726,990, filed on Sep. 5, 2018, and Taiwan application serial no. 108113351, filed on Apr. 17, 2019. The entirety of each of the above-mentioned patent applications is hereby incorporated by reference herein and made a part of this specification.

### TECHNICAL FIELD

The technical field relates to a semiconductor device and a method for fabricating the same.

### BACKGROUND

After continuous research and development of a semiconductor fabrication technology, semiconductor materials required for semiconductor devices have not been limited to silicon materials that are generally used in large quantities. For example, a silicon substrate generally used for a transistor can be replaced by a gallium-containing semiconductor material.

There are many kinds of semiconductor materials in addition to silicon, such as gallium nitride, gallium oxide or SiC, which all have semiconductor characteristics and can be configured to fabricate semiconductor devices. However, in terms of mass production, for example, it is difficult to achieve mass production by using the gallium nitride and the SiC.

A technology of how to fabricate a mass of semiconductor devices with the semiconductor materials in addition to the silicon needs to be considered during the research and development of semiconductor device fabrication.

### SUMMARY

A semiconductor device with a gallium oxide substrate is provided herein.

In one embodiment, the disclosure provides a semiconductor device, including a substrate, a channel layer, a first electrode layer, a second electrode layer and a gate structure. The substrate includes a first gallium oxide layer. The channel layer is disposed on the substrate, where the channel layer is a second gallium oxide layer. The first electrode layer and the second electrode layer are disposed on the channel layer. The gate structure is disposed on the channel layer and located between the first electrode layer and the second electrode layer. The gate structure is on a flat surface of the channel layer or a bottom portion of the gate structure is extended into the channel layer.

In one embodiment, the disclosure provides a method for fabricating a semiconductor device, including: providing a substrate, where the substrate includes a first gallium oxide layer; forming a channel layer on the substrate, where the channel layer is a second gallium oxide layer; forming a first electrode layer and a second electrode layer on the channel layer; and forming a gate structure on the channel layer and between the first electrode layer and the second electrode layer. The gate structure is on a flat surface of the channel layer or a bottom portion of the gate structure is extended into the channel layer.

Several exemplary embodiments accompanied with figures are described in detail below to further describe the disclosure in details.

### BRIEF DESCRIPTION OF THE DRAWINGS

The accompanying drawings are included to provide further understanding, and are incorporated in and constitute a part of this specification. The drawings illustrate exemplary embodiments and, together with the description, serve to explain the principles of the disclosure.

FIG. 1 is a schematic cross-sectional structural view of a transistor according to one embodiment of the disclosure;

FIG. 2 is a schematic cross-sectional structural view of a transistor according to one embodiment of the disclosure;

FIG. 3 is a schematic cross-sectional structural view of a transistor according to one embodiment of the disclosure;

FIG. 4 is a schematic cross-sectional structural view of a transistor according to one embodiment of the disclosure; and

FIG. 5A to FIG. 5G are schematic flow diagrams of a method for fabricating a transistor according to one embodiment of the disclosure.

### DETAILED DESCRIPTION OF DISCLOSED EMBODIMENTS

An embodiment provides a semiconductor device and a method for fabricating the same. The semiconductor device is, for example, a transistor device which uses a substrate including a gallium oxide layer, and a channel layer.

Compared with a silicon material, a semiconductor material with a wider energy gap has better performance, such as the wider energy gap, low on-resistance, high breakdown electric field and lower power loss, which may improve the efficiency of a semiconductor device. Under the condition that a semiconductor substrate is fabricated by a homogenous substrate, compared with a gallium nitride (GaN) or silicon carbide (SiC) semiconductor base material, a semiconductor material of a homogenous base material developed by gallium oxide (Ga₂O₃) easily realizes large-scale and low-cost mass production, which is conductive to, for example, being applied to a high-power device/power module or a switching type power management device. A gallium oxide device may provide materials required for fabrication of the high-power device.

A plurality of embodiments is exemplified below to describe the fabrication of a semiconductor device by using a gallium oxide material, but the disclosure is not limited to the illustrated embodiments. The embodiments may also be appropriately combined to form another embodiment.

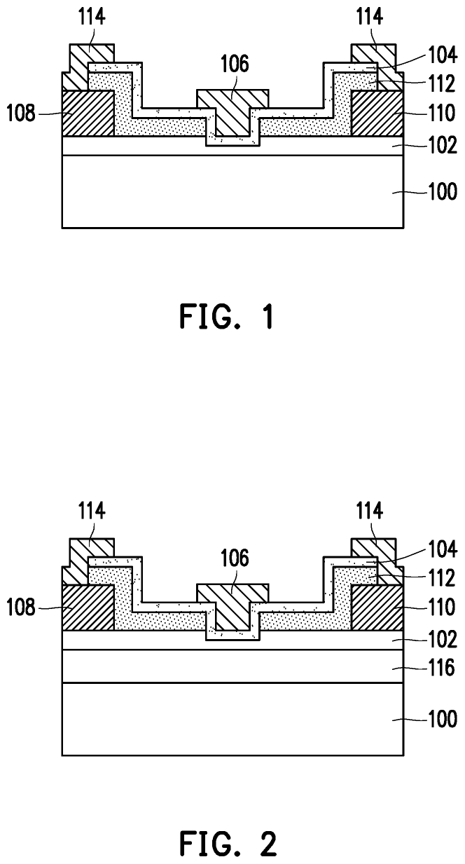

FIG. 1 is a schematic cross-sectional structural view of a transistor according to one embodiment of the disclosure. Referring to FIG. 1, a semiconductor device of a transistor is taken as an example. The structure of the transistor is based on a gallium oxide substrate 100. The substrate 100 is, for example, an α-Ga₂O₃ layer, a β-Ga₂O₃ layer, a combination of the α-Ga₂O₃ layer and a sapphire layer, or a combination of the α-Ga₂O₃ layer, the sapphire layer and a buffer layer (as shown in FIG. 2 below), but the substrate 100 is not limited to the embodiment. That is, Ga₂O₃ is formed, for example, by a process of crystal growth on a base layer. In one of exemplary embodiments, the substrate 100 may also be doped with a dopant. In one of exemplary embodiments, the dopant includes Fe, Be, Mg or Zn.

A channel layer 102 is disposed on the substrate 100. The channel layer 102 is controlled by a gate layer 106 to be operated in the transistor, and a channel region is formed between a first electrode layer 108 and a second electrode layer 110 to control on or off of the transistor. In one of exemplary embodiments, the first electrode layer 108 and the second electrode layer 110 are, for example, regarded as a source and a drain. The gate layer 106 and a gate insulating layer 104 constitute a gate structure. The first electrode layer 108 and the second electrode layer 110 are at two predetermined positions on the channel layer 102. The gate structure is also disposed on the channel layer 102 and located between the first electrode layer 108 and the second electrode layer 110.

In one of exemplary embodiments, the gate structure includes the gate layer 106 and the gate insulating layer 104, and a bottom portion thereof is extended into the channel layer 102, thereby enlarging an effective contact area between the channel layer 102 and the gate layer 106 and changing the way of turning on and turning off the device. In one of exemplary embodiments, the gate insulating layer 104 may, for example, extend to a peripheral region of the gate layer 106 to reach a place above the first electrode layer 108 and the second electrode layer 110. An oxide layer 112 may also be formed in the peripheral region of the gate layer 106 to cover the channel layer 102, the first electrode layer 108 and the second electrode layer 110, as actually needed. The gate insulating layer 104 in the peripheral region of the gate layer 106 is located on the oxide layer 112. In one of exemplary embodiments, a connection structure 114 may also be disposed on the first electrode layer 108 and the second electrode layer 110 in response to the need of connecting the first electrode layer 108 and the second electrode layer 110 to the outside.

In one of exemplary embodiments, the channel layer 102 is, for example, in the range of 10 nm to 1000 nm in thickness. The channel layer 102 may be doped with a dopant corresponding to a desired conductive type. The conductive type includes a P type or an N type. In one of exemplary embodiments, the channel layer 102 is, for example, a single-crystal layer of β-Ga₂O₃ and is doped with a dopant. The dopant is, for example, an N-type dopant provided by Group-IIIA elements of the Periodic Table or a P-type dopant provided by Group-IIA elements of the Periodic Table.

In one of exemplary embodiments, a material of the gate insulating layer 104 includes a ferro-electric material layer or a dielectric layer. The dielectric layer is, for example, a silicon oxide layer. Alternatively, the material of the gate insulating layer 104 includes a composite layer of the ferro-electric material layer and the dielectric layer. The composite layer of the ferro-electric material layer and the dielectric layer is, for example, a laminate of silicon oxide, a ferro-electric material and a dielectric material with a high dielectric value. In one of exemplary embodiments, the ferro-electric material is, for example, one or more combinations of HfZrO₂, LiNbO₃, LiTaO₃, barium titanate (BaTiO₃), potassium dihydrogen phosphate (KH₂PO₄) and the like. In one of exemplary embodiments, the dielectric material with the high dielectric value is, for example, a similar material such as La₂O₃, Al₂O₃, HfO₂, or ZrO₂, and has the dielectric value greater than that of silicon oxide, but the disclosure is not limited to the illustrated embodiments. In one of exemplary embodiments, materials of the first electrode layer 108 and the second electrode layer 110 are, for example, monolayer metal or multilayer metal, such as Au, Al, Ti, Sn, Ge, In, Ni, Co, Pt, W, Mo, Cr, Cu, Pb, Ti/Al, Ti/Au, Ti/Pt, Al/Au, Ni/Au or Au/Ni. In one of exemplary embodiments, the gate layer 106 is, for example, monolayer metal or multilayer metal, such as Au, Al, Ti, Sn, Ge, In, Ni, Co, Pt, W, Mo, Cr, Cu, Pb, Ti/Al, Ti/Au, Ti/Pt, Al/Au, Ni/Au or Au/Ni. However, the material selection of the disclosure is not limited to the illustrated embodiments.

Some modifications may be also made to the semiconductor device based on the gallium oxide as shown in FIG. 1. FIG. 2 is a schematic cross-sectional structural view of a transistor according to one embodiment of the disclosure. Referring to FIG. 2, compared to FIG. 1, same device symbols represent same components, and descriptions thereof are omitted. In the present embodiment, a substrate 100 may further include a buffer layer 116. The substrate 100 and the buffer layer 116 may generally constitute one substrate, that is, the buffer layer 116 may be regarded as one portion of the substrate 100. In one of exemplary embodiments, a material of the buffer layer 116 is, for example, a single-crystal layer of β-Ga₂O₃.

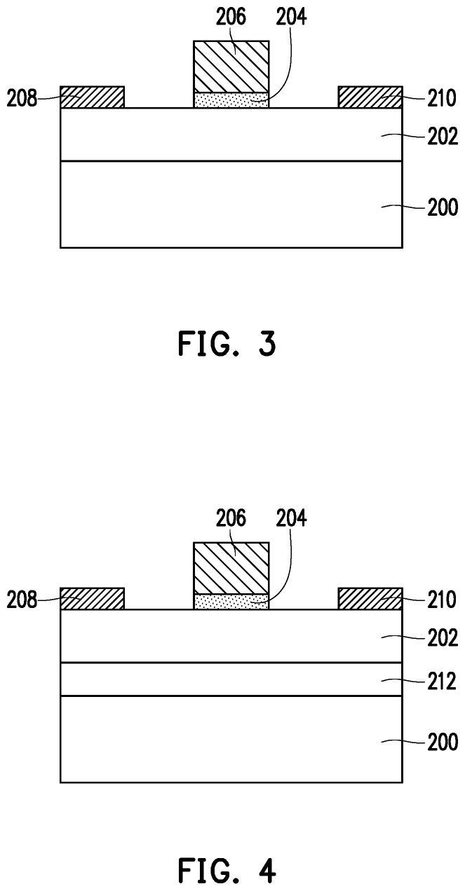

FIG. 3 is a schematic cross-sectional structural view of a transistor according to one embodiment of the disclosure. Referring to FIG. 3, in another embodiment, the structure of the transistor is based on a gallium oxide substrate 200. The substrate 200 is, for example, an α-Ga₂O₃ layer, a β-Ga₂O₃ layer, a combination of the α-Ga₂O₃ layer and a sapphire layer, or a combination of the α-Ga₂O₃ layer, the sapphire layer and a buffer layer (as shown in FIG. 4 below), but the substrate 200 is not limited to the embodiment. That is, Ga₂O₃ is formed, for example, by a process of crystal growth on a base layer. In one of exemplary embodiments, the substrate 200 may also be doped with a dopant. In one of exemplary embodiments, the dopant includes Fe, Be, Mg or Zn.

A channel layer 202 is disposed on the substrate 200. The channel layer 202 is controlled by a gate layer 206 to be operated in the transistor, and a channel region is formed between a first electrode layer 208 and a second electrode layer 210 to control on or off of the transistor. In one of exemplary embodiments, the first electrode layer 208 and the second electrode layer 210 are, for example, regarded as a source and a drain. The gate layer 206 and a gate insulating layer 204 constitute a gate structure. The first electrode layer 208 and the second electrode layer 210 are at two predetermined positions on the channel layer 202. The gate structure is also disposed on the channel layer 202 and located between the first electrode layer 208 and the second electrode layer 210.

In one of exemplary embodiments, the gate structure includes a gate layer 206 and a gate insulating layer 204. In one of exemplary embodiments, compared with the structure of FIG. 1, the structure is that the surface of the channel layer 202 is maintained flat. The gate structure is located on the flat surface of the channel layer 202 and does not extend into the channel layer 202.

In one of exemplary embodiments, the channel layer 202 is, for example, in the range of 10 nm to 1000 nm in thickness. The channel layer 202 may be doped with a dopant corresponding to a desired conductive type. The conductive type includes a P type or an N type. In one of exemplary embodiments, the channel layer 202 is, for example, a single-crystal layer of β-Ga₂O₃ and doped with a dopant. The dopant is, for example, an N-type dopant provided by Group-IIIA elements of the Periodic Table or a P-type dopant provided by Group-IIA elements of the Periodic Table.

In one of exemplary embodiments, a material of the gate insulating layer 204 includes a ferro-electric material layer or a dielectric layer. The dielectric layer is, for example, a silicon oxide layer. Alternatively, the material of the gate insulating layer 204 includes a composite layer of the ferro-electric material layer and the dielectric layer. The composite layer of the ferro-electric material layer and the dielectric layer is, for example, a laminate of silicon oxide, a ferro-electric material and a dielectric material with a high dielectric value. In one of exemplary embodiments, the ferro-electric material is, for example, one or more combinations of HfZrO₂, LiNbO₃, LiTaO₃, barium titanate (BaTiO₃), potassium dihydrogen phosphate (KH₂PO₄) and the like. In one of exemplary embodiments, the dielectric material with a high dielectric value is, for example, La₂O₃, Al₂O₃, HfO₂, or ZrO₂. In one of exemplary embodiments, materials of the first electrode layer 208 and the second electrode layer 210 are, for example, monolayer metal or multilayer metal, such as Au, Al, Ti, Sn, Ge, In, Ni, Co, Pt, W, Mo, Cr, Cu, Pb, Ti/Al, Ti/Au, Ti/Pt, Al/Au, Ni/Au or Au/Ni. In one of exemplary embodiments, the gate layer 106 is, for example, monolayer metal or multilayer metal, such as Au, Al, Ti, Sn, Ge, In, Ni, Co, Pt, W, Mo, Cr, Cu, Pb, Ti/Al, Ti/Au, Ti/Pt, Al/Au, Ni/Au or Au/Ni. However, the material selection of the disclosure is not limited to the illustrated embodiments.

Some modifications may be also made to the semiconductor device based on the gallium oxide as shown in FIG. 3. FIG. 4 is a schematic cross-sectional structural view of a transistor according to one embodiment of the disclosure. Referring to FIG. 4, compared to FIG. 3, same device symbols represent same components, and descriptions thereof are omitted. In the present embodiment, a substrate 200 may further include a buffer layer 212. The substrate 200 and the buffer layer 212 may generally constitute one substrate, that is, the buffer layer 212 may be regarded as one portion of the substrate 200. In one of exemplary embodiments, a material of the buffer layer 212 is, for example, a single-crystal layer of β-Ga₂O₃.

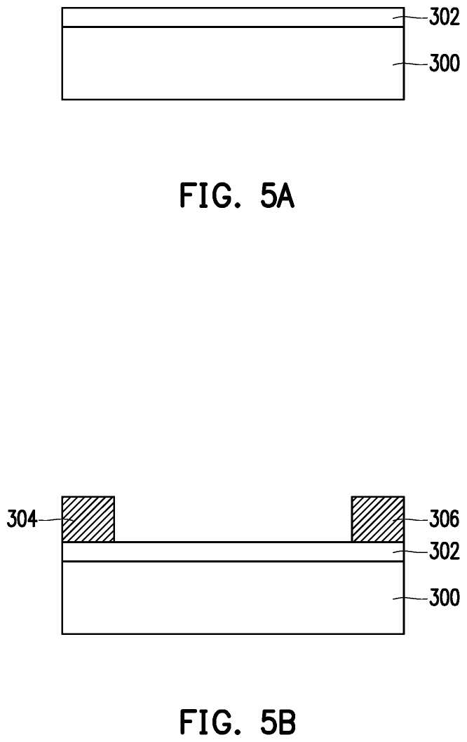

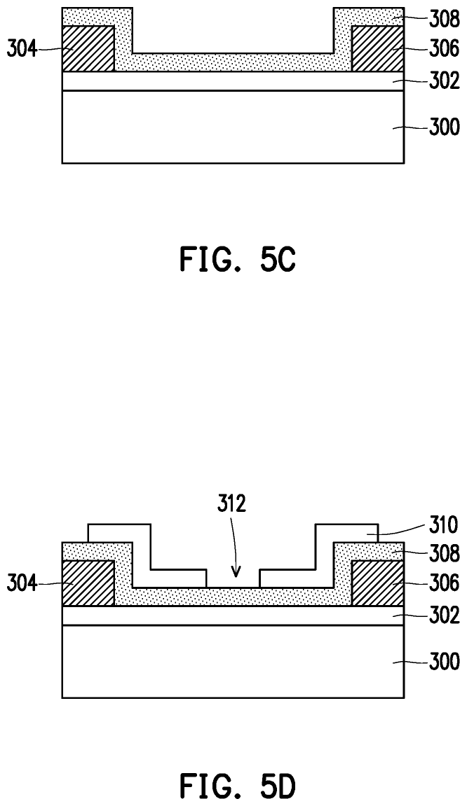

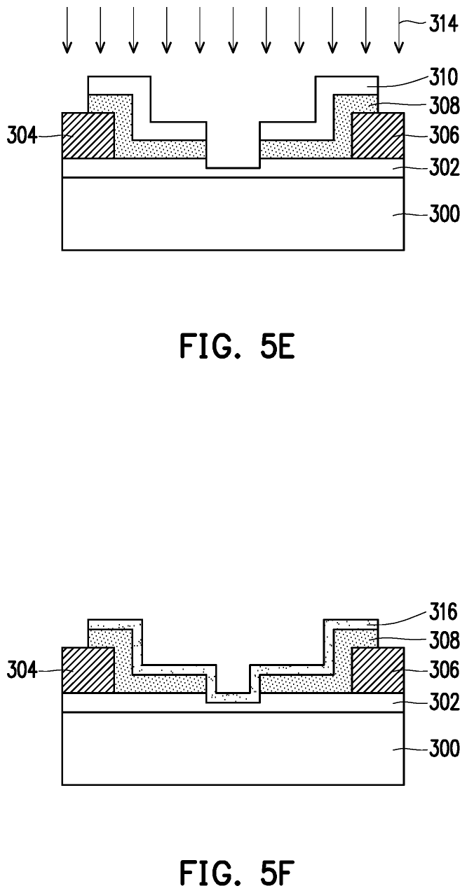

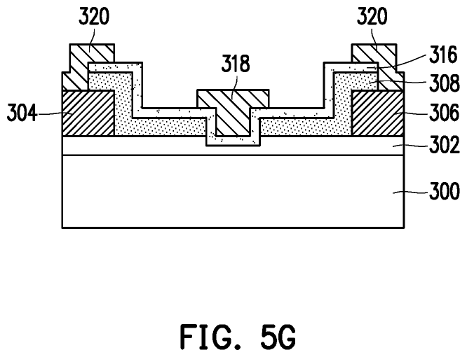

In one of exemplary embodiments, the disclosure further provides a method for fabricating a semiconductor device. FIG. 5A to FIG. 5G are schematic flow diagrams of a method for fabricating a transistor according to one embodiment of the disclosure. Referring to FIG. 5A, a gallium oxide-containing substrate 300 is provided. Further, in one of exemplary embodiments, if the substrate 300 needs buffer layers 116 and 212, the buffer layers 116 and 212 may be correspondingly formed on the substrate 300 and regarded as a partial structure of the substrate 300. Then, a channel layer 302 is formed on the substrate 300.

Referring to FIG. 5B, in one of exemplary embodiments, a photomask is used, and a light source irradiates the channel layer 302, so as to define positions for forming a first electrode layer 304 (for example, a source) and a second electrode layer 306 (for example, a drain). Next, the first electrode layer 304 and the second electrode layer 306 grow on the defined positions. However, the disclosure is not limited to the embodiment, and may also use other semiconductor fabrication procedures to form the first electrode layer 304 and the second electrode layer 306.

Referring to FIG. 5C, in one of exemplary embodiments, an oxide layer 308 is formed above the substrate 300, and covers the first electrode layer 304, the second electrode layer 306 and the channel layer 302. Referring to FIG. 5D, a photoresist pattern layer 310 is formed on the oxide layer 308. The photoresist pattern layer 310 has an opening 312. The photoresist pattern layer 310 in the present embodiment may not completely cover upper sides of the first electrode layer 304 and the second electrode layer 306 to reserve a space to subsequently form an electrode connection structure. The opening 312 corresponds to a predetermined position for subsequently forming a gate structure.

Referring to FIG. 5E, the photoresist pattern layer 310 is an etching mask for performing anisotropic etching 314 to remove an exposed portion of the oxide layer 308. Hereof, the channel layer 302 may also be partially etched to form a recess.

Referring to FIG. 5F, after the photoresist pattern layer 310 is removed, a gate insulating layer 316 is formed on the oxide layer 308. In one of exemplary embodiments, the gate insulating layer 316 may be completed via fabrication procedures, such as deposition, lithography and etching, of a semiconductor, but is not limited to the embodiment.

Referring to FIG. 5G, in one of exemplary embodiments, a gate layer 318 may be formed on the gate insulating layer 316 and corresponds to the recess of the channel layer 302 by using the fabrication procedures, such as deposition, lithography and etching. The gate layer 318 and the gate insulating layer 316 covered by it constitute a gate structure. In the present embodiment, the bottom portion of the gate structure extends into the channel layer 302. In a process of forming the gate layer 318, a connection structure 320 may also be formed simultaneously to contact the first electrode layer 304 and the second electrode layer 306 to provide a connection pad that is subsequently connected to electrodes.

FIG. 5A to FIG. 5G correspond to materials of components of the transistor, as described in FIG. 1 to FIG. 4, so descriptions thereof are omitted herein. Further, the structures of the embodiments of FIG. 1 to FIG. 4 may also be completed through appropriate adjustments and changes according to flows of FIG. 5A to FIG. 5G, which are not described again hereof.

As mentioned above, the semiconductor device and the method for fabricating the same of the disclosure may include the following features.

In one of exemplary embodiments, the disclosure provides a semiconductor device, including a substrate, a channel layer, a first electrode layer, a second electrode layer and a gate structure. The substrate includes a first gallium oxide layer. The channel layer is disposed on the substrate. The channel layer is a second gallium oxide layer. The first electrode layer and the second electrode layer are disposed on the channel layer. The gate structure is disposed on the channel layer and located between the first electrode layer and the second electrode layer. The gate structure is on a flat surface of the channel layer or a bottom portion of the gate structure is extended into the channel layer.

In one of exemplary embodiments, for the semiconductor device, the substrate is of a single layer, or the substrate includes a base layer and a buffer layer on the base layer.

In one of exemplary embodiments, for the semiconductor device, the buffer layer includes a single-crystal material of β-Ga₂O₃.

In one of exemplary embodiments, for the semiconductor device, the substrate includes a semiconductor layer of α-Ga₂O₃, a semiconductor layer of β-Ga₂O₃, a combination of the semiconductor layer of α-Ga₂O₃ and a sapphire layer, or a combination of the semiconductor layer of α-Ga₂O₃, the sapphire layer and a buffer layer.

In one of exemplary embodiments, for the semiconductor device, the gate structure includes: a gate insulating layer, disposed on the channel layer; and a gate layer, disposed on the gate insulating layer. The gate insulating layer includes a ferro-electric material layer or a dielectric layer, or includes a composite layer of the ferro-electric material layer and the dielectric layer.

In one of exemplary embodiments, for the semiconductor device, the composite layer of the ferro-electric material layer and the dielectric layer includes silicon oxide, a ferro-electric material and a dielectric material with a high dielectric value.

In one of exemplary embodiments, for the semiconductor device, the dielectric material with a high dielectric value includes La₂O₃, Al₂O₃, HfO₂, or ZrO₂.

In one of exemplary embodiments, for the semiconductor device, the gate layer includes a metal material.

In one of exemplary embodiments, for the semiconductor device, the channel layer includes a single-crystal layer of β-Ga₂O₃ or a single-crystal layer of α-Ga₂O₃.

In one of exemplary embodiments, for the semiconductor device, a dopant includes an N-type dopant provided by Group-IIIA elements of the Periodic Table or a P-type dopant provided by Group-IIA elements of the Periodic Table.

In one of exemplary embodiments, for the semiconductor device, materials of the first electrode layer and the second electrode layer include monolayer metal or multilayer metal.

In one of exemplary embodiments, the disclosure provides a method for fabricating a semiconductor device, including: providing a substrate, where the substrate includes a first gallium oxide layer; forming a channel layer on the substrate, where the channel layer is a second gallium oxide layer; forming a first electrode layer and a second electrode layer on the channel layer; and forming a gate structure on the channel layer and between the first electrode layer and the second electrode layer. The gate structure is on a flat surface of the channel layer or a bottom portion of the gate structure is extended into the channel layer.

It will be apparent to those skilled in the art that various modifications and variations can be made to the structure of the disclosed embodiments without departing from the scope or spirit of the disclosure. In view of the foregoing, it is intended that the disclosure cover modifications and variations of this disclosure provided they fall within the scope of the following claims and their equivalents.

What is claimed is:

1. A semiconductor device, comprising:
a substrate, having a first gallium oxide layer;
a channel layer, disposed on the substrate, the channel layer being a second gallium oxide layer;
a first electrode layer and a second electrode layer, disposed on the channel layer; and
a gate structure, disposed on the channel layer and located between the first electrode layer and the second electrode layer, wherein
the gate structure is on a flat surface of the channel layer or a bottom portion of the gate structure is extended into the channel layer.

2. The semiconductor device according to claim 1, wherein the substrate is a single layer, or the substrate comprises a base layer and a buffer layer on the base layer.

3. The semiconductor device according to claim 2, wherein the buffer layer comprises a single-crystal material of β-Ga₂O₃ or a single-crystal layer of α-Ga₂O₃.

4. The semiconductor device according to claim 1, wherein the substrate comprises a semiconductor layer of α-Ga₂O₃, a semiconductor layer of β-Ga₂O₃, a combination of the semiconductor layer of α-Ga₂O₃ and a sapphire layer, or a combination of the semiconductor layer of α-Ga₂O₃, the sapphire layer and a buffer layer.

5. The semiconductor device according to claim 1, wherein the gate structure comprises:
a gate insulating layer, disposed on the channel layer; and
a gate layer, disposed on the gate insulating layer, wherein
the gate insulating layer comprises a ferro-electric material layer or a dielectric layer, or comprises a composite layer of the ferro-electric material layer and the dielectric layer.

6. The semiconductor device according to claim 5, wherein the composite layer of the ferro-electric material layer and the dielectric layer is silicon oxide, a ferro-electric material and a dielectric material with a high dielectric value.

7. The semiconductor device according to claim 6, wherein the dielectric material with a high dielectric value comprises La₂O₃, Al₂O₃, HfO₂, or ZrO₂.

8. The semiconductor device according to claim 5, wherein the gate layer comprises a metal material.

9. The semiconductor device according to claim 1, wherein the channel layer comprises a single-crystal layer of β-Ga₂O₃ or a single-crystal layer of α-Ga₂O₃.

10. The semiconductor device according to claim 9, wherein a dopant comprises an N-type dopant provided by Group-IIIA elements of the Periodic Table or a P-type dopant provided by Group-IIA elements of the Periodic Table.

11. The semiconductor device according to claim 1, wherein materials of the first electrode layer and the second electrode layer comprise monolayer metal or multilayer metal.

12. A method for fabricating a semiconductor device, comprising:
providing a substrate having a first gallium oxide layer;
forming a channel layer on the substrate, the channel layer being a second gallium oxide layer;
forming a first electrode layer and a second electrode layer on the channel layer; and
forming a gate structure on the channel layer and disposed between the first electrode layer and the second electrode layer, wherein the gate structure is on a flat surface of the channel layer, or a bottom portion of the gate structure is extended into the channel layer.

13. The method for fabricating the semiconductor device according to claim 12,
wherein the step of forming the gate structure comprises:
forming a gate insulating layer on the channel layer; and
forming a gate layer on the gate insulating layer, wherein
the gate insulating layer comprises a ferro-electric material layer or a dielectric layer, or comprises a composite layer of the ferro-electric material layer and the dielectric layer.
